(19) United States
(12) Patent Application Publication
(10) Pub. No.: US 2024/0387415 A1
(43) Pub. Date: Nov. 21, 2024

(54) NITRIDE SEMICONDUCTOR DEVICE AND MANUFACTURING METHOD THEREFOR

(71) Applicant: ROHM CO., LTD., Kyoto-shi (JP)

(72) Inventor: Keita SHIKATA, Kyoto-shi (JP)

(73) Assignee: ROHM CO., LTD., Kyoto-shi (JP)

(21) Appl. No.: 18/788,312

(22) Filed: Jul. 30, 2024

Related U.S. Application Data
(63) Continuation of application No. PCT/JP2023/001382, filed on Jan. 18, 2023.

(30) Foreign Application Priority Data
Feb. 22, 2022 (JP) 2022-025598

(51) Int. Cl. H01L 23/64; H01L 29/26; H01L 29/66; H01L 29/778

(52) U.S. Cl. CPC H01L 23/647; H01L 29/26; H01L 29/66462; H01L 29/778

(57) ABSTRACT

A nitride semiconductor device includes an SiC substrate having a first principal surface and a second principal surface at an opposite side thereto, a low resistance SiC layer that is formed on the first principal surface and is lower in resistivity than the SiC substrate, a high resistance SiC layer that is formed on the low resistance SiC layer and is higher in resistivity than the low resistance SiC layer, and a nitride epitaxial layer that is disposed on the high resistance SiC layer.

### CROSS-REFERENCE TO RELATED APPLICATIONS

The present application is a continuation application of PCT Application No. PCT/JP2023/001382, filed on Jan. 18, 2023, which corresponds to Japanese Patent Application No. 2022-025598 filed on Feb. 22, 2022, with the Japan Patent Office, and the entire disclosure of this application is incorporated herein by reference.

### TECHNICAL FIELD

The present disclosure relates to a nitride semiconductor device that is constituted of a group III nitride semiconductor (hereinafter referred to at times simply as “nitride semiconductor”) and a manufacturing method therefor.

### BACKGROUND ART

A group III nitride semiconductor is a semiconductor among group III-V semiconductors with which nitrogen is used as the group V element. Aluminum nitride (AlN), gallium nitride (GaN), and indium nitride (InN) are representative examples thereof. It can generally be expressed as AlₓIn_{y}Ga_{1-x-y}N (0≤x≤1, 0≤y≤1, 0≤x+y≤1).

As a nitride semiconductor device installed in a high frequency amplifier, there is known an HEMT (high electron mobility transistor) that includes a semi-insulating SiC substrate having satisfactory heat dissipation, a nitride epitaxial layer formed on the SiC substrate, and a source electrode, a gate electrode, and a drain electrode disposed on the nitride epitaxial layer.

With the HEMT installed in the high frequency amplifier, in order to stabilize the ground, a back electrode is formed on a rear surface of the SiC substrate and the source electrode and the back electrode are electrically connected via a via that penetrates through a laminated body of the SiC substrate and the nitride epitaxial layer.

However, there is a problem in that forming of the via hole in the SiC substrate requires high cost and thus a manufacturing cost of the HEMT becomes high.

In Japanese Translation of International Application (Kohyo) No. 2008-536332 is disclosed a semiconductor device structure in which a conductive SiC substrate is used as the SiC substrate and the conductive SiC substrate itself is made to function as the ground. However, when the conductive SiC substrate is used as the SiC substrate, the nitride epitaxial layer must be thickened to reduce a parasitic capacitance. However, thickening of the nitride epitaxial layer becomes a factor that causes warping of the conductive SiC substrate and internal cracking in the nitride epitaxial layer.

### BRIEF DESCRIPTION OF DRAWINGS

FIG. 1 is a sectional view for describing the arrangement of a nitride semiconductor device according to a first preferred embodiment of the present disclosure.

FIG. 2A is a sectional view showing an example of a manufacturing process of the nitride semiconductor device.

FIG. 2B is a sectional view showing a step subsequent to that of FIG. 2A.

FIG. 2C is a sectional view showing a step subsequent to that of FIG. 2B.

FIG. 2D is a sectional view showing a step subsequent to that of FIG. 2C.

FIG. 2E is a sectional view showing a step subsequent to that of FIG. 2D.

FIG. 2F is a sectional view showing a step subsequent to that of FIG. 2E.

FIG. 2G is a sectional view showing a step subsequent to that of FIG. 2F.

FIG. 2H is a sectional view showing a step subsequent to that of FIG. 2G.

FIG. 2I is a sectional view showing a step subsequent to that of FIG. 2H.

FIG. 2J is a sectional view showing a step subsequent to that of FIG. 2I.

FIG. 3 is a sectional view for describing the arrangement of a nitride semiconductor device according to a second preferred embodiment of the present disclosure.

### DESCRIPTION OF EMBODIMENTS

A preferred embodiment of the present disclosure provides a nitride semiconductor device including an SiC substrate having a first principal surface and a second principal surface opposite thereto, a low resistance SiC layer that is formed on the first principal surface and is lower in resistivity than the SiC substrate, a high resistance SiC layer that is formed on the low resistance SiC layer and is higher in resistivity than the low resistance SiC layer, and a nitride epitaxial layer that is disposed on the high resistance SiC layer.

With this arrangement, the nitride semiconductor device by which it is made possible to suppress warping of the SiC substrate and internal cracking of the nitride epitaxial layer can be obtained.

With the preferred embodiment of the present disclosure, the resistivity of the low resistance SiC layer is not more than 0.01 Ω·cm and the resistivity of the high resistance SiC layer is not less than 10 Ω·cm.

With the preferred embodiment of the present disclosure, the resistivity of the low resistance SiC layer is not more than 0.002 Ω·cm.

With the preferred embodiment of the present disclosure, the resistivity of the low resistance SiC layer is not more than 0.0002 Ω·cm.

With the preferred embodiment of the present disclosure, the resistivity of the high resistance SiC layer is not less than 1×10³ Ω·cm.

With the preferred embodiment of the present disclosure, the resistivity of the high resistance SiC layer is not less than 1×10⁴ Ω·cm.

With the preferred embodiment of the present disclosure, the resistivity of the high resistance SiC layer is not less than 1×10⁵ Ω·cm.

With the preferred embodiment of the present disclosure, a thickness of the low resistance SiC layer is not less than 2 μm.

With the preferred embodiment of the present disclosure, a thickness of the high resistance SiC layer is not less than 5 μm.

With the preferred embodiment of the present disclosure, a thickness of the nitride epitaxial layer is not more than 2.5 μm.

With the preferred embodiment of the present disclosure, in the high resistance SiC layer, more deep energy levels including either or both of levels with energy depths from conduction band of not less than 0.6 eV and not more than 0.7 eV and not less than 1.5 eV and not more than 1.6 eV are formed than shallow donor levels.

With the preferred embodiment of the present disclosure, the nitride epitaxial layer includes a buffer layer that is constituted of a nitride semiconductor, a first nitride semiconductor layer that is formed on the buffer layer and constitutes an electron transit layer, and a second nitride semiconductor layer that is formed on the first nitride semiconductor layer, constitutes an electron supply layer, and is higher in bandgap than the first nitride semiconductor layer.

With the preferred embodiment of the present disclosure, a semi-insulating nitride layer that is interposed between the buffer layer and the first nitride semiconductor layer is included.

With the preferred embodiment of the present disclosure, the buffer layer includes an AlN layer at a lower layer side and an AlGaN layer at an upper layer side that is formed on the AlN layer, the semi-insulating nitride layer is a semi-insulating GaN layer that is doped with an impurity, the first nitride semiconductor layer is a non-doped GaN layer that is formed on the semi-insulating GaN layer, and the second nitride semiconductor layer includes an AlGaN layer.

With the preferred embodiment of the present disclosure, a source electrode, a drain electrode, and a gate electrode that are disposed on the nitride epitaxial layer are included, a contact hole reaching from a front surface of the nitride epitaxial layer to an intermediate thickness of the low resistance SiC layer is formed, and the source electrode is electrically connected to the low resistance SiC layer via the contact hole.

With the preferred embodiment of the present disclosure, a source electrode, a drain electrode, and a gate electrode that are disposed on the nitride epitaxial layer are included, a contact hole reaching from a front surface of the nitride epitaxial layer to an intermediate thickness of the SiC substrate is formed, and the source electrode is electrically connected to the SiC substrate via the contact hole.

With the preferred embodiment of the present disclosure, a rear surface electrode that is formed on the second principal surface is included.

A preferred embodiment of the present disclosure provides a method for manufacturing a nitride semiconductor device including a step of forming, on a first principal surface of an SiC substrate having the first principal surface and a second principal surface opposite thereto, a low resistance SiC layer that is lower in resistivity than the SiC substrate, a step of forming, on the low resistance SiC layer, a high resistance SiC layer that is higher in resistivity than the low resistance SiC layer, and a step of forming a nitride epitaxial layer on the high resistance SiC layer.

With this manufacturing method, the nitride semiconductor device by which it is made possible to suppress warping of the SiC substrate and internal cracking of the nitride epitaxial layer can be manufactured.

In the following, preferred embodiments of the present disclosure shall be described in detail with reference to the accompanying drawings.

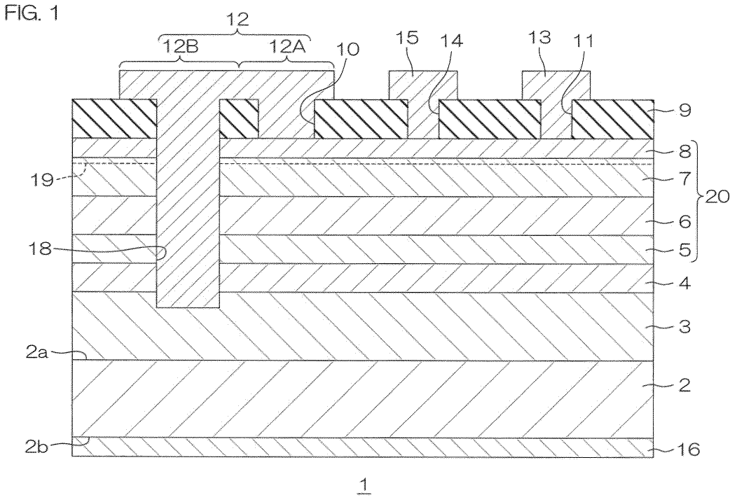

FIG. 1 is a sectional view for describing the arrangement of a nitride semiconductor device according to a first preferred embodiment of the present disclosure.

The nitride semiconductor device 1 includes an SiC substrate 2 having a first principal surface (front surface) 2a and a second principal surface (rear surface) 2b at an opposite side thereto, a low resistance SiC layer 3 that is formed on the first principal surface 2a of the SiC substrate 2 and is lower in resistivity than the SiC substrate 2, a high resistance SiC layer 4 that is formed on the low resistance SiC layer 3 and is higher in resistivity than the low resistance SiC layer 3, and a nitride epitaxial layer 20 that is disposed on the high resistance SiC layer 4.

The nitride epitaxial layer 20 includes a buffer layer 5 that is formed on the high resistance SiC layer 4, a semi-insulating nitride layer 6 that is formed on the buffer layer 5, a first nitride semiconductor layer 7 that is formed on the semi-insulating nitride layer 6, and a second nitride semiconductor layer 8 that is formed on the first nitride semiconductor layer 7.

Further, the nitride semiconductor device 1 includes an insulating film 9 that is formed on the second nitride semiconductor layer 8. Further, the nitride semiconductor device 1 includes a source electrode 12 and a drain electrode 13 that respectively penetrate through a source contact hole 10 and a drain contact hole 11 formed in the insulating film 9 and are in ohmic contact with the second nitride semiconductor layer 8. The source electrode 12 and the drain electrode 13 are disposed at an interval.

Further, the nitride semiconductor device 1 includes a gate electrode 15 that penetrates through a gate contact hole 14 formed in the insulating film 9 and is in contact with the second nitride semiconductor layer 8. The gate electrode 15 is disposed between the source electrode 12 and the drain electrode 13. Further, the nitride semiconductor device 1 includes a back electrode 16 that is formed on the second principal surface 2b of the SiC substrate 2.

Here, in actuality, source electrodes (S) 12, gate electrodes (G9) 15, and drain electrodes (D) 13 are disposed side by side in the order of SGDGSGDG . . . on the second nitride semiconductor layer 8.

In this preferred embodiment, the SiC substrate 2 is a conductive SiC substrate. A thickness of the SiC substrate 2 is approximately 100 μm. A resistivity of the SiC substrate 2 is approximately 0.02 Ω·cm. The SiC substrate 2 is doped with a donor type impurity. A concentration of the donor type impurity may be approximately 1×10¹⁸ cm⁻³. The donor type impurity is, for example, nitrogen (N).

A resistivity of the low resistance SiC layer 3 is preferably not more than 0.02 Ω·cm, more preferably not more than 0.002 Ω·cm, and even more preferably not more than 0.0002 Ω·cm. A thickness of the low resistance SiC layer 3 is preferably not less than 2 μm. In this preferred embodiment, the thickness of the low resistance SiC layer 3 is approximately 3 μm. The low resistance SiC layer 3 is doped with a donor type impurity. A concentration of the donor type impurity is approximately 1×10²⁰ cm⁻³. The donor type impurity is, for example, nitrogen (N).

A resistivity of the high resistance SiC layer 4 is preferably not less than 10 Ω·cm, more preferably not less than 1×10³ Ω·cm, more preferably not less than 1×10⁴ Ω·cm, and even more preferably not less than 1×10⁵ Ω·cm. A thickness of the high resistance SiC layer 4 is preferably not less than 5 μm. In this preferred embodiment, the thickness of the high resistance SiC layer 4 is approximately 10 μm.

The buffer layer 5 is a buffer layer that buffers strain resulting from mismatch of a lattice constant of the semi-insulating nitride layer 6 formed on the buffer layer 5 and a lattice constant of the high resistance SiC layer 4. In this preferred embodiment, the buffer layer 5 is constituted of a multilayer buffer layer in which a plurality of nitride semiconductor films are laminated. In this preferred embodiment, the buffer layer 5 is constituted of a laminated film of an AlN film in contact with a front surface of the high resistance SiC layer 4 and an AlGaN film laminated on a front surface (surface at an opposite side to the high resistance SiC layer 4) of the AlN film. The buffer layer 5 may instead be constituted of a single film of an AlN film or a single film of an AlGaN. A thickness of the buffer layer 5 is, for example, approximately 0.01 μm to 0.1 μm. In this preferred embodiment, the thickness of the buffer layer 5 is approximately 0.01 μm.

The semi-insulating nitride layer 6 is provided to suppress a leak current. The semi-insulating nitride layer 6 is constituted of a GaN layer that is doped with an impurity and a thickness thereof is approximately 0.3 μm to 1.2 μm. In this preferred embodiment, the thickness of the semi-insulating nitride layer 6 is approximately 1 μm. The impurity is, for example, C (carbon) and is doped such that a difference between an acceptor concentration Na and a donor concentration Nd (Na−Nd) is approximately 5×10¹⁷ cm⁻³.

The first nitride semiconductor layer 7 constitutes an electron transit layer. In this preferred embodiment, the first nitride semiconductor layer 7 is constituted of an n-type GaN layer that is doped with a donor type impurity and a thickness thereof is, for example, approximately 0.05 μm to 1 μm. In this preferred embodiment, the thickness of the first nitride semiconductor layer 7 is approximately 0.1 μm. Also, the first nitride semiconductor layer 7 may be constituted of a non-doped GaN layer instead.

The second nitride semiconductor layer 8 constitutes an electron supply layer. The second nitride semiconductor layer 8 is constituted of a nitride semiconductor of greater bandgap than the first nitride semiconductor layer 7. Specifically, the second nitride semiconductor layer 8 is constituted of a nitride semiconductor of higher Al composition than the first nitride semiconductor layer 7. In a nitride semiconductor, the higher the Al composition, the greater the bad gap. In this preferred embodiment, the second nitride semiconductor layer 8 is constituted of an Alₓ₁Ga₁₋ₓ₁N layer (0<x1≤1) and a thickness thereof is, for example, approximately 1 nm to 100 nm. In this preferred embodiment, the thickness of the second nitride semiconductor layer 8 is approximately 20 nm and x1=0.2.

A thickness of the nitride epitaxial layer 20 is preferably not more than 2.5 μm.

The first nitride semiconductor layer 7 (electron transit layer) and the second nitride semiconductor layer 8 (electron supply layer) are thus constituted of nitride semiconductors that differ in bandgap (Al composition) and a lattice mismatch occurs therebetween. Also, due to spontaneous polarizations of the first nitride semiconductor layer 7 and the second nitride semiconductor layer 8 and a piezo polarization due to the lattice mismatch between the two, an energy level of a conduction band of the first nitride semiconductor layer 7 at an interface between the first nitride semiconductor layer 7 and the second nitride semiconductor layer 8 is made lower than a Fermi level. Thereby, inside the first nitride semiconductor layer 7, a two-dimensional electron gas (2DEG) 19 spreads at a position close to the interface of the first nitride semiconductor layer 7 and the second nitride semiconductor layer 8 (for example, at a distance of only several Å from the interface).

The insulating film 9 is formed across substantially an entire area of a front surface of the second nitride semiconductor layer 8. In this preferred embodiment, the insulating film 9 is constituted of SiN. A thickness of the insulating film 9 is, for example, approximately 10 nm to 200 nm. In this preferred embodiment, the thickness of the insulating film 9 is approximately 100 nm. Besides SiN, the insulating film 9 may be constituted of SiO₂, SiN, SiON, Al₂O₃, AlN, AlON, HfO, HfN, HfON, HfSiON, AlON, etc.

In the low resistance SiC layer 3, the high resistance SiC layer 4, the nitride epitaxial layer 20, and the insulating film 9, a ground contact hole 18 that penetrates continuously through the insulating film 9, the nitride epitaxial layer 20, and the high resistance SiC layer 4 from a front surface of the insulating film 9 and extends to an intermediate thickness of the low resistance SiC layer 3 is formed at an opposite side from the gate contact hole 14 with respect to the source contact hole 10.

The source electrode 12 includes a main electrode portion 12A and an extension portion 12B. The main electrode portion 12A covers the source contact hole 10 and a peripheral edge portion of the source contact hole 10 at the insulating film 9 front surface. A portion of the main electrode portion 12A enters into the source contact hole 10 and contacts the front surface of the second nitride semiconductor layer 8 inside the source contact hole 10.

The extension portion 12B covers the ground contact hole 18 and a peripheral edge portion of the ground contact hole 18 at the insulating film 9 front surface. A side edge of the extension portion 12B at the main electrode portion 12A side and a side edge of the main electrode portion 12A at the extension portion 12B side are connected. A portion of the extension portion 12B enters into the ground contact hole 18 and contacts the low resistance SiC layer 3 inside the ground contact hole 18.

The drain electrode 13 covers the drain contact hole 11 and a peripheral edge portion of the drain contact hole 11 at the insulating film 9 front surface. A portion of the drain electrode 13 enters into the drain contact hole 11 and contacts the front surface of the second nitride semiconductor layer 8 inside the drain contact hole 11.

The source electrode 12 and the drain electrode 13 are each constituted, for example, of a Ti/Al laminated film in which a Ti film and an Al film are laminated in that order from a lower layer. A thickness of the Ti film at the lower layer side is, for example, approximately 20 nm and a thickness of the Al film at an upper layer side is, for example, approximately 300 nm.

The source electrode 12 and the drain electrode 13 suffice to be constituted of a material with which ohmic contact can be established with respect to the second nitride semiconductor layer 8 (AlGaN layer). The source electrode 12 and the drain electrode 13 may each be constituted of a Ti/Al/Ni/Au laminated film in which a Ti film, an Al film, an Ni film, and an Au film are laminated in that order from a lower layer.

The gate electrode 15 covers the gate contact hole 14 and a peripheral edge portion of the gate contact hole 14 at the insulating film 9 front surface. A portion of the gate electrode 15 enters into the gate contact hole 14 and contacts the front surface of the second nitride semiconductor layer 8 inside the gate contact hole 14.

The gate electrode 15 is constituted, for example, of an Ni/Au laminated film in which an Ni film and an Au film are laminated in that order from a lower layer. A thickness of the Ni film at the lower layer side is, for example, approximately 10 nm and a thickness of the Au film at an upper layer side is, for example, approximately 600 nm. The gate electrode 15 suffices to be constituted of a material with which a Schottky barrier can be formed with respect to the second nitride semiconductor layer 8 (AlGaN layer).

The back electrode 16 is formed such as to cover substantially an entire area of the second principal surface 2b of the SiC substrate 2. The back electrode 16 is constituted, for example, of an Ni film. The back electrode 16 is electrically connected to the main electrode portion 12A of the source electrode 12 via the SiC substrate 2, the low resistance SiC layer 3, and the extension portion 12B of the source electrode 12.

With the nitride semiconductor device 1, a heterojunction is formed by there being formed, on the first nitride semiconductor layer 7 (electron transit layer), the second nitride semiconductor layer 8 (electron supply layer) that differs in bandgap (Al composition). Thereby, the two-dimensional electron gas 19 is formed inside the first nitride semiconductor layer 7 near the interface of the first nitride semiconductor layer 7 and the second nitride semiconductor layer 8 and an HEMT that uses the two-dimensional electron gas 19 as a channel is formed.

In a state where a control voltage is not applied to the gate electrode 15, the source electrode 12 and the drain electrode 13 are electrically connected to each other with the two-dimensional electron gas 19 as the channel. Therefore, the HEMT is of a normally-on type. When the control voltage such that a potential at the gate electrode 15 is made negative with respect to the source electrode 12 is applied to the gate electrode 15, the two-dimensional electron gas 19 is interrupted and the HEMT is put in an off state.

With the present preferred embodiment, the low resistance SiC layer 3 that is lower in resistivity than the SiC substrate 2 is formed on the first principal surface 2a of the SiC substrate 2. Also, the source electrode 12 (a plurality of source electrodes 12) is electrically connected to the low resistance SiC layer 3. A potential gradient at a vicinity of the low resistance SiC layer 3 front surface in contact with the high resistance SiC layer 4 can thereby be decreased in comparison to a potential gradient of an SiC substrate 2 interior in a vicinity of the first principal surface 2a in a case where the high resistance SiC layer 4 is formed directly on the first principal surface 2a of the SiC substrate 2 without insertion of the low resistance SiC layer 3. Loss during device operation can thereby be reduced.

With the present preferred embodiment, since the low resistance SiC layer 3 is formed on the first principal surface 2a of the SiC substrate 2, if no measures are taken, the nitride epitaxial layer 20 must be thickened to reduce a parasitic capacitance, as in a case where a conductive SiC substrate is used as the SiC substrate 2. However, thickening of the nitride epitaxial layer becomes a factor that causes warping of the conductive SiC substrate and internal cracking in the nitride epitaxial layer.

With the present preferred embodiment, since the high resistance SiC layer 4 that is higher in resistivity than the low resistance SiC layer 3 is formed on the low resistance SiC layer 3, the parasitic capacitance can be reduced in comparison to a case where the high resistance SiC layer 4 is not formed on the low resistance SiC layer 3. It is thereby made possible to decrease the film thickness of the nitride epitaxial layer 20. It is thereby made possible to suppress warping of the conductive SiC substrate and internal cracking of the nitride epitaxial layer.

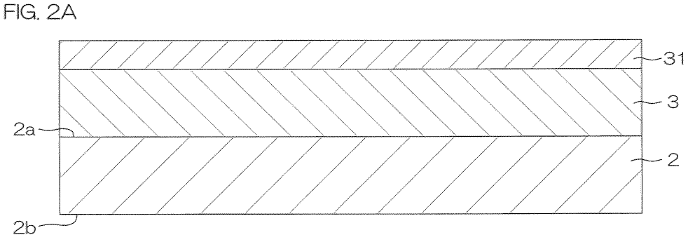

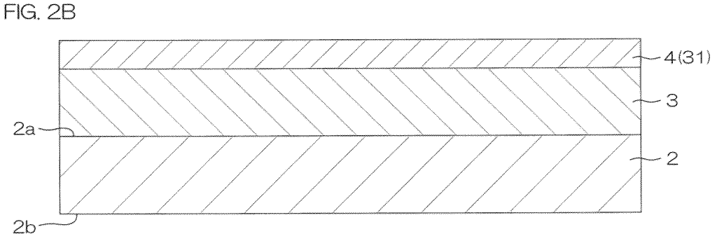

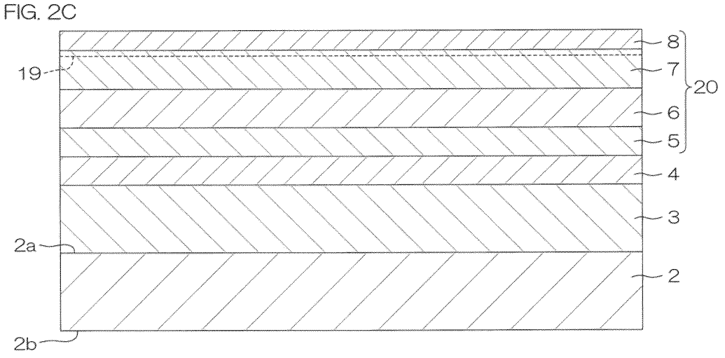

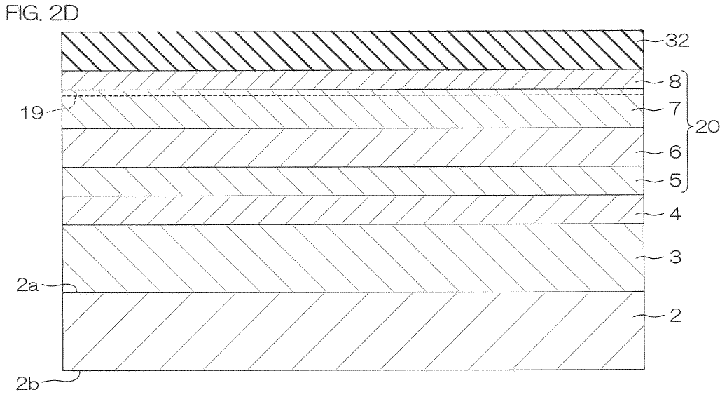

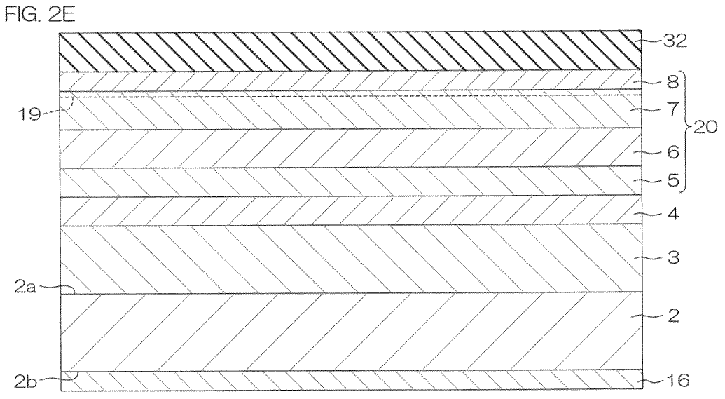

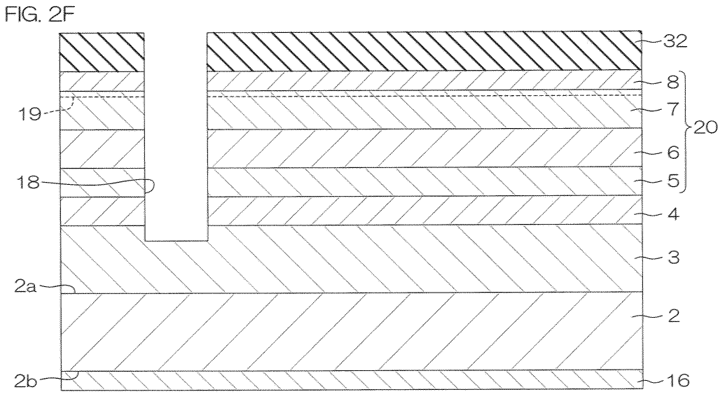

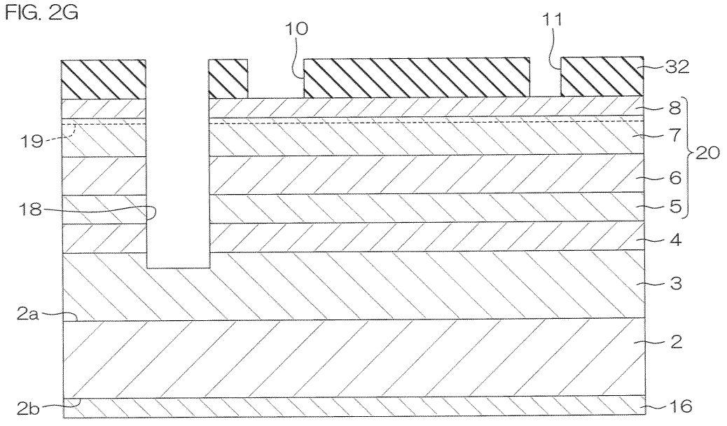

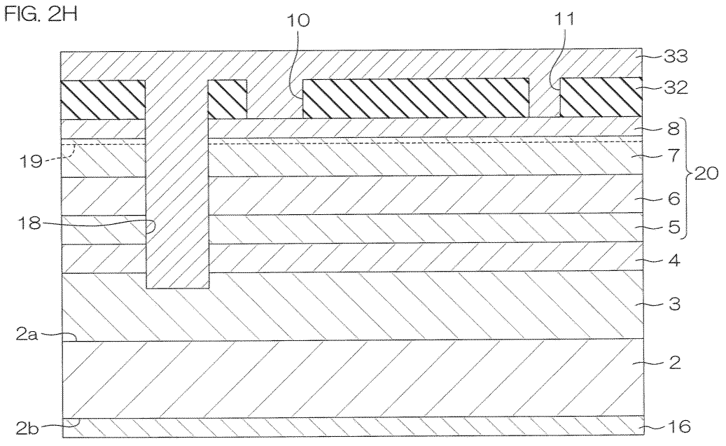

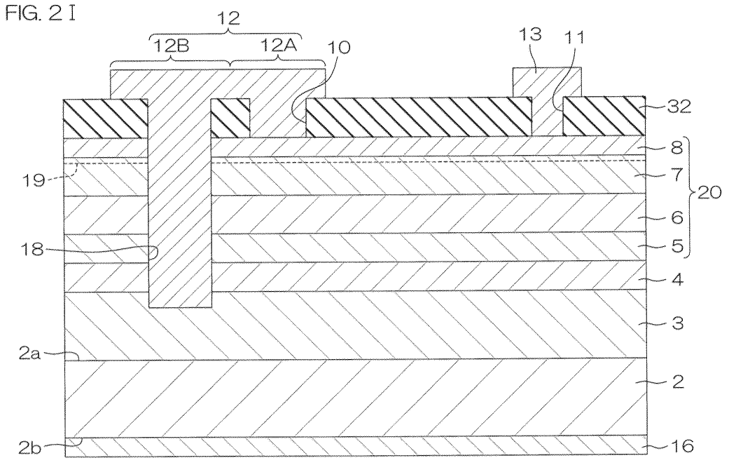

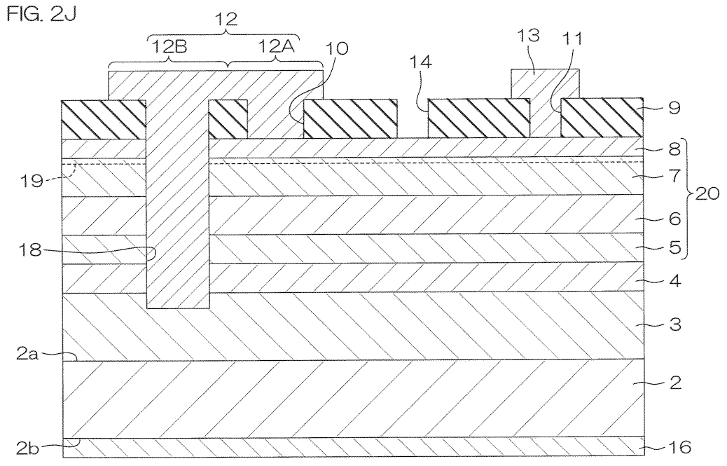

FIG. 2A to FIG. 2J are sectional views for describing an example of a manufacturing process of the nitride semiconductor device 1 described above and show a sectional structure in a plurality of stages of the manufacturing process.

First, as shown in FIG. 2A, the low resistance SiC layer 3 and a non-doped SiC layer 31 are epitaxially grown in that order on the first principal surface 2a of the SiC substrate 2, for example, by a CVD (chemical vapor deposition) method. The non-doped SiC layer 31 is an SiC layer for forming the high resistance SiC layer 4. It is possible to form the low resistance SiC layer 3 and the non-doped SiC layer 31 by switching an impurity concentration. The impurity concentration of the low resistance SiC layer 3 is approximately 1×10²⁰ cm⁻³ and the impurity concentration of the non-doped SiC layer 31 is approximately 1×10¹⁵ cm⁻³. A thickness of the non-doped SiC layer 31 is approximately 10 μm.

Next, as shown in FIG. 2B, electron beam irradiation is performed on the non-doped SiC layer 31. Thereby, the high resistance SiC layer 4 with which more deep energy levels including either or both of levels with energy depths from conduction band of not less than 0.6 eV and not more than 0.7 eV and not less than 1.5 eV and not more than 1.6 eV are formed than shallow donor levels is obtained. In the electron beam irradiation step, an acceleration voltage is preferably not less than 200 KV and not more than 800 kV and a fluence is preferably not less than 1×10¹⁷ cm⁻².

Also, the high resistance SiC layer 4 may instead be formed by performing ion implantation, proton implantation, etc., on the non-doped SiC layer 31.

Next, as shown in FIG. 2C, the buffer layer 5, the semi-insulating nitride layer 6, the first nitride semiconductor layer (electron transit layer) 7, and the second nitride semiconductor layer (electron supply layer) 8 are epitaxially grown successively on the high resistance SiC layer 4, for example, by a CVD method. Thereby, the nitride epitaxial layer 20 constituted of the buffer layer 5, the semi-insulating nitride layer 6, the first nitride semiconductor layer 7, and the second nitride semiconductor layer 8 is formed on the high resistance SiC layer 4.

Next, as shown in FIG. 2D, an insulating material film 32 that is a material film of the insulating film 9 is formed on the second nitride semiconductor layer 8 by a plasma CVD method, LPCVD (low pressure CVD) method, MOCVD method, sputtering method, etc.

Next, as shown in FIG. 2E, the back electrode 16 is formed on the second principal surface 2b of the SiC substrate 2. The back electrode 16 is prepared, for example, by forming an Ni film on the second principal surface 2b of the SiC substrate 2 by a sputtering method.

Next, a resist film (not shown) is formed on the insulating material film 32 in a region excluding a region in which the ground contact hole 18 is to be formed. By portions of the insulating material film 32, the nitride epitaxial layer 20, the high resistance SiC layer 4, and the low resistance SiC layer 3 being dry etched via the resist film, the ground contact hole 18 that penetrates continuously through the insulating material film 32, the nitride epitaxial layer 20, and the high resistance SiC layer 4 and reaches an interior of the low resistance SiC layer 3 is formed as shown in FIG. 2F.

Thereafter, the resist film is removed. A resist film (not shown) is then formed on the insulating material film 32 in a region excluding regions in which the source contact hole 10 and the drain contact hole 11 are to be formed. By the insulating material film 32 being dry etched via the resist film, the source contact hole 10 and the drain contact hole 11 are formed in the insulating material film 32 as shown in FIG. 2G. The source contact hole 10 and the drain contact hole 11 penetrate through the insulating material film 32 and reach the second nitride semiconductor layer 8. Thereafter, the resist film is removed.

Next, as shown in FIG. 2H, for example, by an electron beam vapor deposition method, sputtering method, etc., an electrode film 33 that is a material film of the source electrode 12 and the drain electrode 13 is formed on the second nitride semiconductor layer 8 such as to cover the insulating material film 32. The electrode film 33 is constituted, for example, of a Ti/Al laminated film in which a Ti film and an Al film are laminated in that order from a lower layer.

Next, a resist film that covers a source electrode preparation planned region and a drain electrode preparation planned region of the electrode film 33 front surface is formed. By the electrode film 33 then being etched selectively using the resist film as a mask, the source electrode 12 including the main electrode portion 12A and the extension portion 12B and the drain electrode 13 are obtained as shown in FIG. 2I.

Next, a resist film (not shown) is formed on the insulating material film 32, the source electrode 12, and the drain electrode 13 in a region excluding a region in which the gate contact hole 14 is to be formed. By the insulating material film 32 being dry etched via the resist film, the gate contact hole 14 is formed in the insulating material film 32 as shown in FIG. 2J. The insulating material film 32 is thereby patterned and the insulating film 9 is obtained. The gate contact hole 14 penetrates through the insulating film 9 and reaches the second nitride semiconductor layer 8.

Next, by the gate electrode 15 being formed after removing the resist film, the nitride semiconductor device 1 such as shown in FIG. 1 is obtained. The gate electrode 15 is constituted, for example, of an Ni/Au laminated film in which an Ni film and an Au film are laminated in that order from a lower layer.

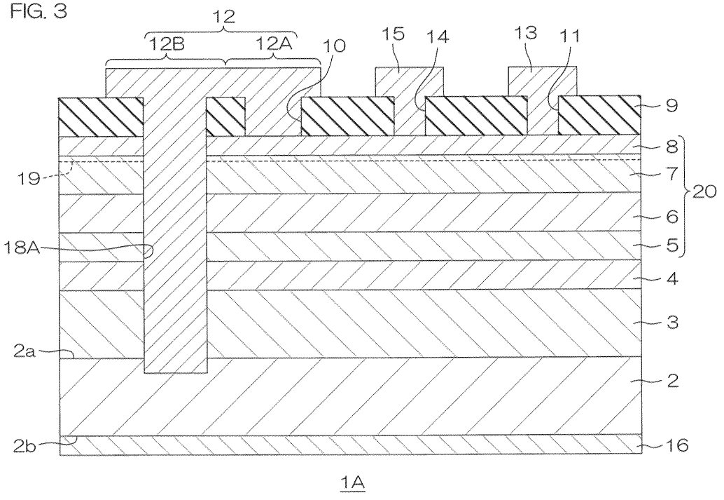

FIG. 3 is a sectional view for describing the arrangement of a nitride semiconductor device according to a second preferred embodiment of the present disclosure. In FIG. 3, portions corresponding to respective portions in FIG. 1 are indicated with the same reference signs attached as in FIG. 1.

In comparison to the nitride semiconductor device 1 of FIG. 1, the nitride semiconductor device 1A of FIG. 3 differs in the point that a lower end of a ground contact hole 18A reaches an intermediate thickness of the SiC substrate 2.

Specifically, the ground contact hole 18A penetrates continuously through the insulating film 9, the nitride epitaxial layer 20, the high resistance SiC layer 4, and the low resistance SiC layer 3 from the front surface of the insulating film 9 and extends to an intermediate thickness of the SiC substrate 2. A portion of the extension portion 12B of the source electrode 12 enters into the ground contact hole 18A and contacts the SiC substrate 2 inside the ground contact hole 18A. Therefore, with this preferred embodiment, the back electrode 16 is electrically connected to the main electrode portion 12A of the source electrode 12 via the SiC substrate 2 and the extension portion 12B of the source electrode 12.

Also, a method for manufacturing the nitride semiconductor device 1A of FIG. 3 is the same as the method for manufacturing the nitride semiconductor device 1 of FIG. 1 except for the following point. That is, in the method for manufacturing the nitride semiconductor device 1A of FIG. 3, in the step of FIG. 2F described above, the ground contact hole 18A that penetrates continuously through the insulating material film 32, the nitride epitaxial layer 20, the high resistance SiC layer 4, and the low resistance SiC layer 3 and reaches the interior of the SiC substrate 2 is formed.

Although the semi-insulating nitride layer 6 is formed on the buffer layer 5 in the first and second preferred embodiments described above, the semi-insulating nitride layer 6 does not have to be formed.

Also, although with each of the first and second preferred embodiments described above, a description has been given of an example where the first nitride semiconductor layer (electron transit layer) 7 is constituted of a GaN layer and the second nitride semiconductor layer (electron supply layer) 8 is constituted of an AlGaN layer, it suffices that the first nitride semiconductor layer 7 and the second nitride semiconductor layer 8 differ in bandgap (for example, in Al composition) and other combinations are also possible. For example, as combinations of the first nitride semiconductor layer 7/second nitride semiconductor layer 8, GaN/AlN, AlGaN/AlN, etc., can be given as examples.

While preferred embodiments of the present disclosure were described in detail above, these are merely specific examples used to clarify the technical contents of the present disclosure and the present disclosure should not be interpreted as being limited to these specific examples and the scope of the present disclosure is limited only by the appended claims.

1. A nitride semiconductor device comprising:
an SiC substrate having a first principal surface and a second principal surface opposite thereto;
a low resistance SiC layer that is formed on the first principal surface and is lower in resistivity than the SiC substrate;
a high resistance SiC layer that is formed on the low resistance SiC layer and is higher in resistivity than the low resistance SiC layer; and
a nitride epitaxial layer that is disposed on the high resistance SiC layer.

2. The nitride semiconductor device according to claim 1, wherein the resistivity of the low resistance SiC layer is not more than 0.01 Ω·cm and the resistivity of the high resistance SiC layer is not less than 10 Ω·cm.

3. The nitride semiconductor device according to claim 2, wherein the resistivity of the low resistance SiC layer is not more than 0.002 Ω·cm.

4. The nitride semiconductor device according to claim 2, wherein the resistivity of the low resistance SiC layer is not more than 0.0002 Ω·cm.

5. The nitride semiconductor device according to claim 2, wherein the resistivity of the high resistance SiC layer is not less than 1×10³ Ω·cm.

6. The nitride semiconductor device according to claim 2, wherein the resistivity of the high resistance SiC layer is not less than 1×10⁴ Ω·cm.

7. The nitride semiconductor device according to claim 2, wherein the resistivity of the high resistance SiC layer is not less than 1×10⁵ Ω·cm.

8. The nitride semiconductor device according to claim 1, wherein a thickness of the low resistance SiC layer is not less than 2 μm.

9. The nitride semiconductor device according to claim 1, wherein a thickness of the high resistance SiC layer is not less than 5 μm.

10. The nitride semiconductor device according to claim 1, wherein a thickness of the nitride epitaxial layer is not more than 2.5 μm.

11. The nitride semiconductor device according to claim 1, wherein, in the high resistance SiC layer, more deep energy levels including either or both of levels with energy depths from conduction band of not less than 0.6 eV and not more than 0.7 eV and not less than 1.5 eV and not more than 1.6 eV are formed than shallow donor levels.

12. The nitride semiconductor device according to claim 1, wherein the nitride epitaxial layer includes
a buffer layer that is constituted of a nitride semiconductor,
a first nitride semiconductor layer that is formed on the buffer layer and constitutes an electron transit layer, and
a second nitride semiconductor layer that is formed on the first nitride semiconductor layer, constitutes an electron supply layer, and is higher in bandgap than the first nitride semiconductor layer.

13. The nitride semiconductor device according to claim 12, comprising: a semi-insulating nitride layer that is interposed between the buffer layer and the first nitride semiconductor layer.

14. The nitride semiconductor device according to claim 13, wherein the buffer layer includes an AlN layer at a lower layer side and an AlGaN layer at an upper layer side that is formed on the AlN layer,
the semi-insulating nitride layer is a semi-insulating GaN layer that is doped with an impurity,
the first nitride semiconductor layer is a non-doped GaN layer that is formed on the semi-insulating GaN layer, and
the second nitride semiconductor layer includes an AlGaN layer.

15. The nitride semiconductor device according to claim 1, comprising: a source electrode; a drain electrode; and a gate electrode that are disposed on the nitride epitaxial layer; and
wherein a contact hole reaching from a front surface of the nitride epitaxial layer to an intermediate thickness of the low resistance SiC layer is formed and
the source electrode is electrically connected to the low resistance SiC layer via the contact hole.

16. The nitride semiconductor device according to claim 1, comprising: a source electrode; a drain electrode; and a gate electrode that are disposed on the nitride epitaxial layer; and
wherein a contact hole reaching from a front surface of the nitride epitaxial layer to an intermediate thickness of the SiC substrate is formed, and
the source electrode is electrically connected to the SiC substrate via the contact hole.

17. The nitride semiconductor device according to claim 15, comprising: a rear surface electrode that is formed on the second principal surface.

18. The nitride semiconductor device according to claim 16, comprising: a rear surface electrode that is formed on the second principal surface.

19. A method for manufacturing a nitride semiconductor device comprising:
a step of forming, on a first principal surface of an SiC substrate having the first principal surface and a second principal surface opposite thereto, a low resistance SiC layer that is lower in resistivity than the SiC substrate;
a step of forming, on the low resistance SiC layer, a high resistance SiC layer that is higher in resistivity than the low resistance SiC layer; and
a step of forming a nitride epitaxial layer on the high resistance SiC layer.
